(19) United States
(12) Patent Application Publication
(10) Pub. No.: US 2011/0089941 A1
(43) Pub. Date: Apr. 21, 2011

(54) MAGNETIC SENSOR AND MAGNETIC SENSOR MODULE

(76) Inventor: Hiromitsu Sasaki, Miyagi-Ken (JP)

(21) Appl. No.: 12/982,023

(22) Filed: Dec. 30, 2010

Related U.S. Application Data
(63) Continuation of application No. PCT/JP2009/063065, filed on Jan. 21, 2009.

(30) Foreign Application Priority Data
Jul. 22, 2008 (JP) 2008-188061

(51) Int. Cl. G01R 33/02

(52) U.S. Cl. 324/252

(57) ABSTRACT

An element connection body includes an element portion, an intermediate permanent magnet layer, and an outer permanent magnet layer. The element portion has recessed portions formed in an upper surface or a lower surface of a non-magnetic layer or formed midway in the thickness direction of the non-magnetic layer from a free magnetic layer. The permanent magnet layers are formed in the recessed portions. The permanent magnet layers and an overall thickness of the free magnetic layer face each other in the element length direction of the element portion. A fixed magnetic layer extends, without being separated, over an entirety in the element length direction of the element connection body.

### CLAIM OF PRIORITY

This application is a Continuation of International Application No. PCT/JP2009/063065 filed on Jan. 21, 2009, which claims benefit of Japanese Patent Application No. 2008-188061 filed on Jul. 22, 2008. The entire contents of each application noted above are hereby incorporated by reference.

### BACKGROUND

1. Field of the Invention

The present invention relates to a magnetic sensor having magnetoresistance effect elements, which may be used as, for example, a geomagnetic sensor.

2. Description of the Related Art

Magnetic sensors having magnetoresistance effect elements can be used as, for example, geomagnetic sensors that are incorporated in mobile devices such as mobile phones and that are configured to sense the geomagnetism. The value of electrical resistance of the magnetoresistance effect elements fluctuates with respect to the intensity of the magnetic field from the sensitivity axis direction.

Japanese Unexamined Patent Application Publication No. 2006-66821 discloses a giant magnetoresistance (GMR) element including narrow band-shaped portions 11a1 to 11a6, a plurality of end bias magnet films 11b1 to 11b7, a pair of terminal portions 11c1 and 11c2, and a plurality of center bias magnet films 11d1 to 11d6 (see paragraphs [0022] to [0031] and FIGS. 2 and 3 in Japanese Unexamined Patent Application Publication No. 2006-66821).

The end bias magnet films 11b1 to 11b7 and the center bias magnet films 11d1 to 11d6 form the narrow band-shaped portions 11a1 to 11a6, and are provided to supply a bias magnetic field to a free magnetic layer F whose magnetization direction varies in response to an external magnetic field (see paragraph [0038] in Japanese Unexamined Patent Application Publication No. 2006-66821).

As illustrated in FIG. 3 in Japanese Unexamined Patent Application Publication No. 2006-66821, the center bias magnet films 11d1 to 11d6 and the end bias magnet films 11b1 to 11b7 are formed on a substrate 10a. Then, the narrow band-shaped portions 11a1 to 11a6 are formed so as to overlay the substrate 10a and the end bias magnet films 11b1 to 11b7 and the center bias magnet films 11d1 to 11d6. In other words, the narrow band-shaped portions 11a1 to 11a6 are formed to override the center bias magnet films 11d1 to 11d6 and the end bias magnet films 11b1 to 11b7.

In the above configuration, however, the narrow band-shaped portions 11a1 to 11a6 are formed to be wavy. Additionally, a leakage magnetic field produced around and above the bias magnet films 11b1 to 11b7 and 11d1 to 11d6 acts on the free magnetic layer F or a fixed magnetic layer P located above the bias magnet films 11b1 to 11b7 and 11d1 to 11d6. As a result, disadvantageously, the uniaxial anisotropy of the free magnetic layer F and the fixed magnetic layer P is reduced, and it is difficult to improve the detection accuracy.

Furthermore, instead of using a configuration in which, as in Japanese Unexamined Patent Application Publication No. 2006-66821, an element portion (narrow band-shaped portions) is formed on the top of a permanent magnet layer, a configuration in which the stacking order is reversed, that is, as illustrated in FIG. 14, a permanent magnet layer 71 is provided on the top surface of an element portion 70 having a portion where a fixed magnetic layer, a non-magnetic layer, and a free magnetic layer are stacked, would control the magnetization of the free magnetic layer only with a leakage magnetic field leaking downward from the permanent magnet layer 71, and it is difficult to improve the uniaxial anisotropy of the free magnetic layer.

To address the foregoing problems with the related art, the present invention provides a magnetic sensor and a magnetic sensor module that, in particular, allow the improvement of the uniaxial anisotropy of both a fixed magnetic layer and a free magnetic layer.

### SUMMARY OF THE INVENTION

According to an aspect of the present invention, a magnetic sensor includes a magnetoresistance effect element. The magnetoresistance effect element includes an element portion having a fixed magnetic layer having a fixed magnetization direction, a non-magnetic layer stacked on the fixed magnetic layer, and a free magnetic layer stacked on the non-magnetic layer, the non-magnetic layer being provided between the fixed magnetic layer and the free magnetic layer, the free magnetic layer having a magnetization direction varying in response to an external magnetic field. The fixed magnetization direction of the fixed magnetic layer is oriented in an element width direction of the element portion that is a sensitivity axis direction. The element portion has recessed portions at a plurality of positions midway in an element length direction thereof perpendicular to the element width direction, the recessed portions being formed in a thickness direction of the element portion. The magnetoresistance effect element further includes a first permanent magnet layer provided in the recessed portions, and an element connecting body including the element portion and the first permanent magnet layer. The recessed portions are formed in an upper surface or a lower surface of the non-magnetic layer or are formed midway in a thickness direction of the non-magnetic layer from the free magnetic layer. The first permanent magnet layer formed in the recessed portions and an overall thickness of the free magnetic layer face each other in the element length direction. The fixed magnetic layer extends, without being separated, over an entirety in an element length direction of the element connecting body.

Therefore, the uniaxial anisotropy of the free magnetic layer and the fixed magnetic layer can be improved, and the detection accuracy can also be improved.

In the present invention, preferably, the element portion is configured such that the fixed magnetic layer, the non-magnetic layer, and the free magnetic layer are stacked in order from the bottom. Therefore, the element portion can be formed prior to the formation of the permanent magnet layer, and, in addition, the element portion can be formed on a flat surface. Thus, the element portion can be easily formed as desired.

In the present invention, preferably, the recessed portions are formed midway in the thickness direction of the non-magnetic layer from the free magnetic layer. Therefore, a portion of the free magnetic layer is not left in the area where the permanent magnet layer is to be formed. In addition, no damage is applied to the fixed magnetic layer during the formation of the recessed portions. Moreover, in terms of electrical contact, the contact with a non-magnetic layer having a low resistance value is achieved.

Further, in the present invention, preferably, a non-magnetic low-resistance layer having a lower resistance value than the first permanent magnet layer is formed on a surface of the first permanent magnet layer opposite to a surface facing the fixed magnetic layer in such a manner that the non-magnetic low-resistance layer overlaps the first permanent magnet layer. Therefore, the parasitic resistance other than the element resistance can be reduced.

Further, in the present invention, preferably, the magnetoresistance effect element further includes second permanent magnet layers provided on both sides in the element length direction of the element portion in such a manner that the second permanent magnet layers are in contact with the element portion or are spaced apart from the element portion. In this case, preferably, the element portion further has recessed portions at both sides in the element length direction thereof, and the second permanent magnet layers are formed in the recessed portions.

Further, in the present invention, a length in an element length direction of each of the second permanent magnet layers may be longer than a length in an element length direction of the first permanent magnet layer. Thus, the bias magnetic field applied from outside can be prevented from being weaker than the bias magnetic field in the vicinity of the center.

Further, in the present invention, a width of the first permanent magnet layer and a width of each of the second permanent magnet layers may be larger than a width of the element portion. Thus, a portion near the corners of a permanent magnet layer pattern where the bias magnetic field is significantly strong can be prevented from having an direct influence on the element portion.

Further, in the present invention, a plurality of element connecting bodies may be arranged with intervals therebetween in the element width direction, and outer permanent magnet layers provided at both sides of each of the plurality of element connecting bodies may be electrically connected to each other using a non-magnetic connection layer so that the plurality of element connecting bodies are formed into a meandering shape. The formation of a meandering element connection body can increase the element resistance and can reduce the power consumption.

According to another aspect of the present invention, a magnetic sensor module includes a plurality of magnetic sensors each having the configuration described above, and magnetoresistance effect elements of the plurality of magnetic sensors are arranged so that a sensitivity axis of a magnetoresistance effect element of at least one of the plurality of magnetic sensors is perpendicular to a sensitivity axis of a magnetoresistance effect element of the other magnetic sensors. For example, a magnetic sensor module according to an aspect of the present invention can be used as a geomagnetic sensor.

### BRIEF DESCRIPTION OF THE DRAWINGS

FIG. 1A is a plan view illustrating a portion of a magnetic sensor according to a first embodiment, particularly, magnetoresistance effect elements;

FIG. 1B is a partial cross-sectional view taken along the line IB-IB in FIG. 1A in the height direction (in FIG. 1B, the Z direction), as viewed from the direction of the arrow;

FIG. 2 is a plan view illustrating a portion of a magnetic sensor according to a second embodiment, particularly, magnetoresistance effect elements;

FIG. 3 is a partial enlarged cross-sectional view taken along the line III-III in FIG. 2 in the height direction (in FIG. 3, the Z direction), as viewed from the direction of the arrow;

FIG. 4 is a partial enlarged plan view illustrating a preferred element connecting body;

FIG. 5 is a plan view of a fixed magnetic layer according to the embodiments;

FIG. 6 is a partial enlarged cross-sectional view of FIG. 3;

FIG. 7 is a partial cross-sectional view of an element connecting body according to another embodiment;

FIG. 8 is a diagram describing a relationship between the fixed magnetization direction of a fixed magnetic layer and the magnetization direction of a free magnetic layer of a magnetoresistance effect element, and the value of electrical resistance;

FIG. 9 is a cross-sectional view illustrating a cross section of the element portion, taken in the thickness direction;

FIG. 10 is a circuit diagram of a magnetic sensor according to the embodiments;

FIG. 11 is a perspective view of a geomagnetic sensor (magnetic sensor module);

FIG. 12 is a cross-sectional view of an element connecting body in a comparative example;

FIG. 13 is a plan view of a fixed magnetic layer and a permanent magnet layer in the comparative example, and schematically illustrates a magnetic domain structure; and

FIG. 14 is a cross-sectional view of an element portion and a permanent magnet layer of the related art.

### DESCRIPTION OF THE PREFERRED EMBODIMENTS

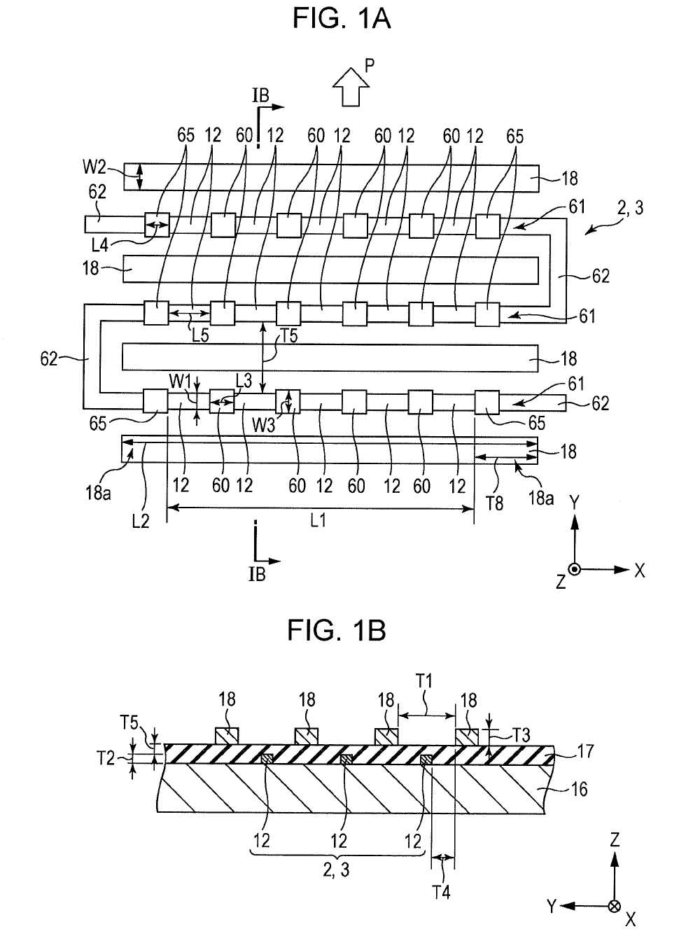

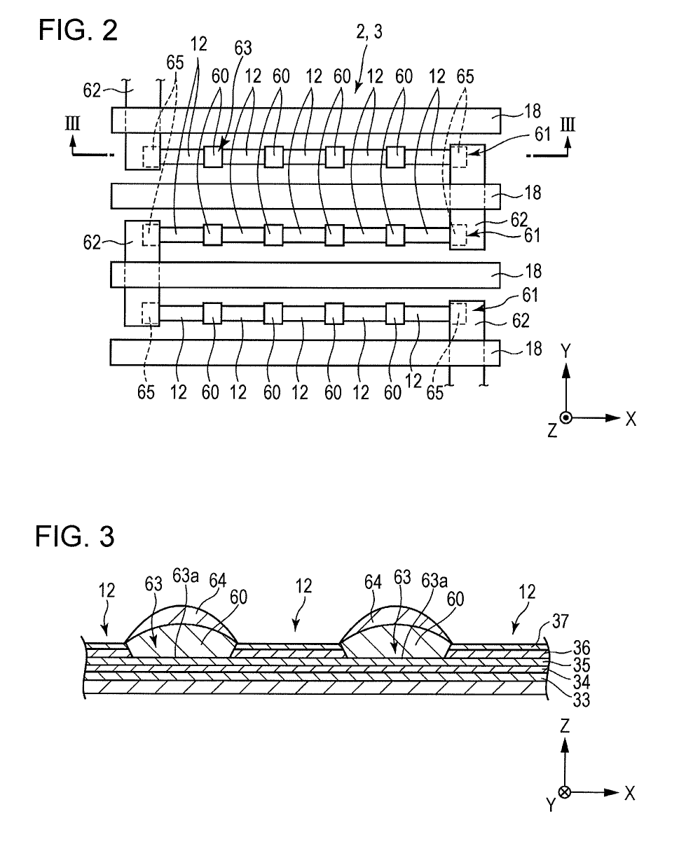

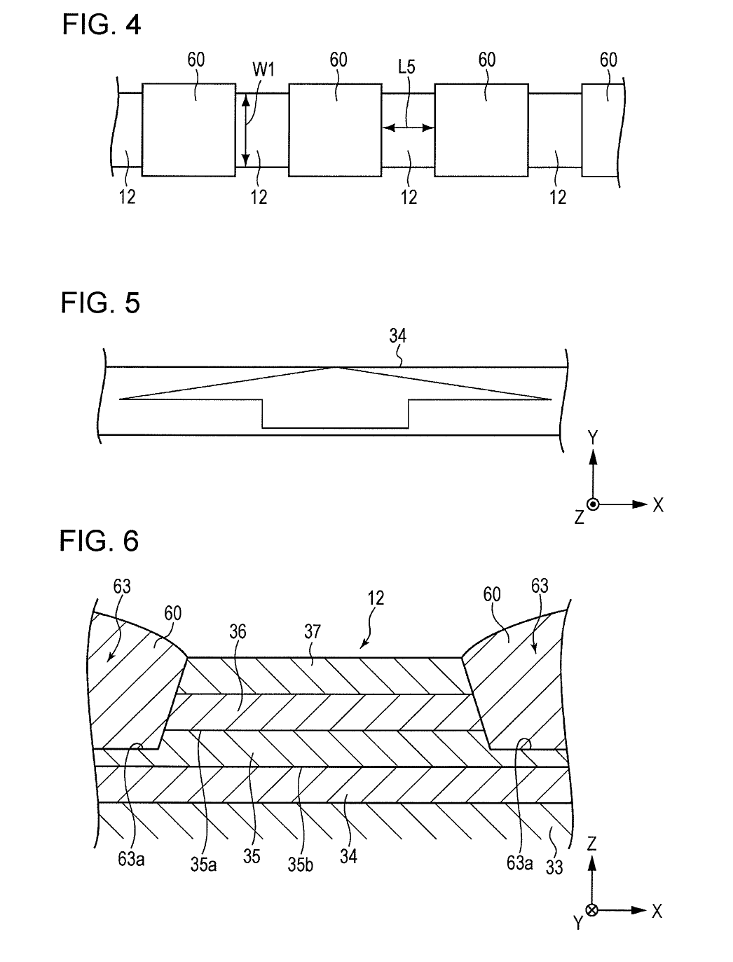

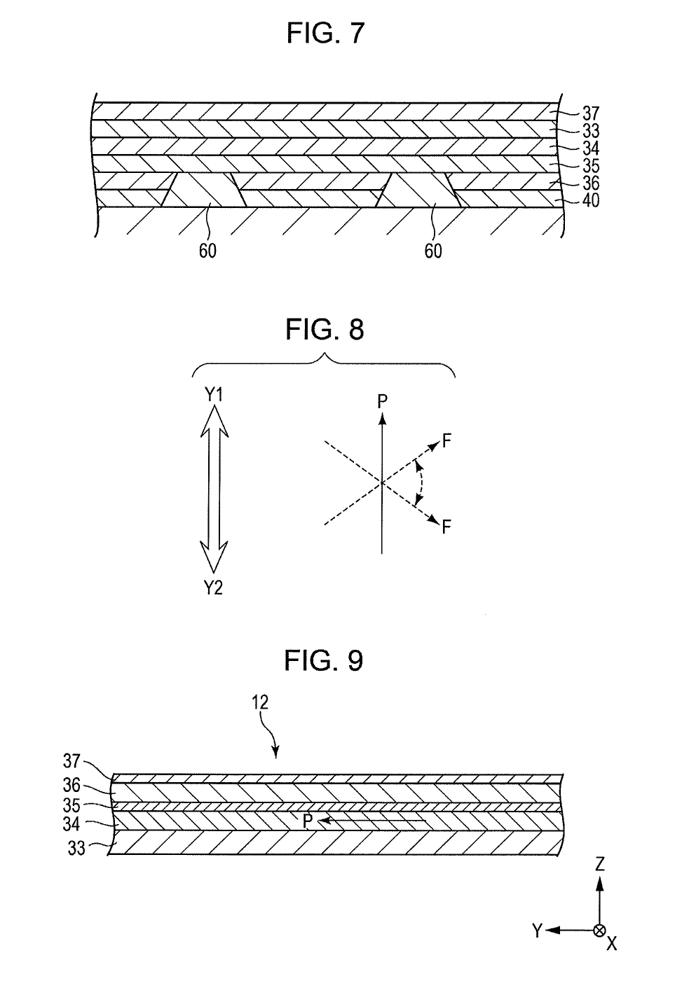

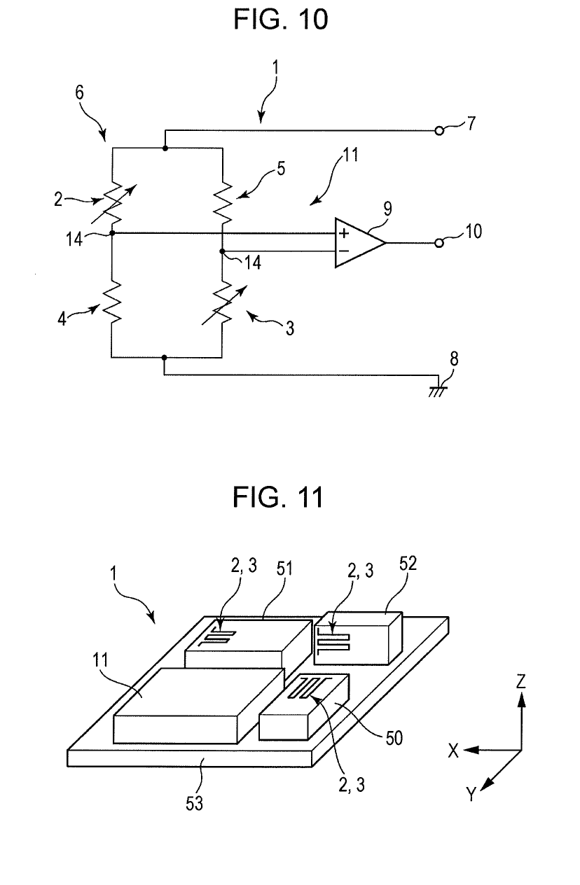

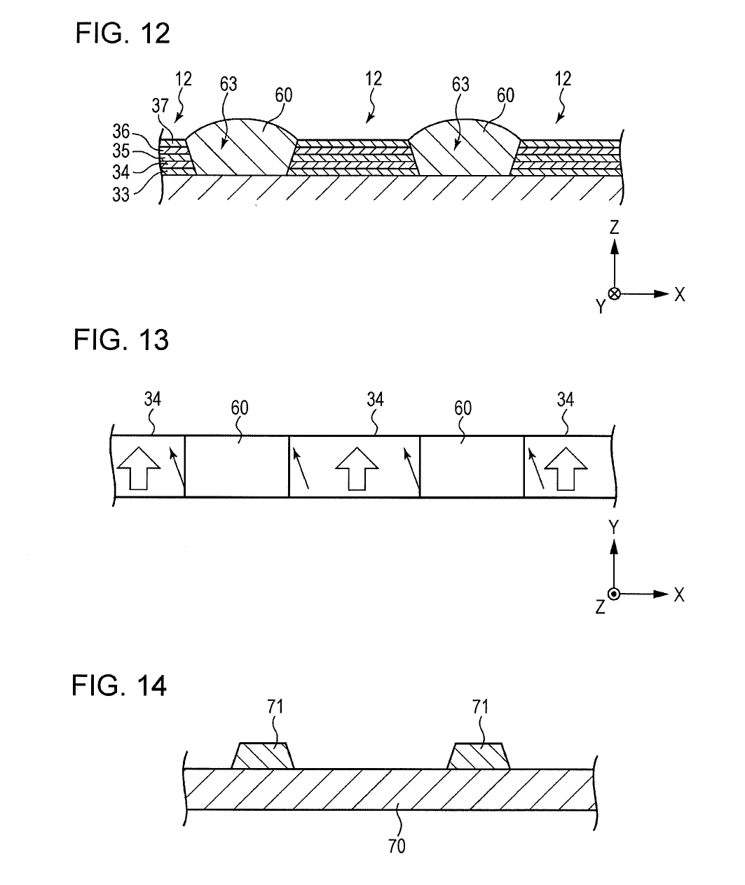

FIG. 1A is a plan view illustrating a portion of a magnetic sensor according to a first embodiment, particularly, magnetoresistance effect elements, and FIG. 1B is a partial cross-sectional view taken along the line IB-IB in FIG. 1A in the height direction (in FIG. 1B, the Z direction), as viewed from the direction of the arrow. FIG. 2 is a plan view illustrating a portion of a magnetic sensor according to a second embodiment, particularly, magnetoresistance effect elements, and FIG. 3 is a partial enlarged cross-sectional view taken along the line III-III in FIG. 2 in the height direction (in FIG. 3, the Z direction), as viewed from the direction of the arrow. FIG. 4 is a partial enlarged plan view illustrating a preferred element connecting body, and FIG. 5 is a plan view of a fixed magnetic layer according to the embodiments. FIG. 6 is a partial enlarged cross-sectional view of FIG. 3. FIG. 7 is a partial cross-sectional view of an element connecting body according to another embodiment, and FIG. 8 is a diagram describing a relationship between the fixed magnetization direction of a fixed magnetic layer and the magnetization direction of a free magnetic layer of a magnetoresistance effect element, and the value of electrical resistance. FIG. 9 is a cross-sectional view illustrating a cross section of the element portion, taken in the thickness direction, and FIG. 10 is a circuit diagram of a magnetic sensor according to the embodiments. FIG. 11 is a partial perspective view of a geomagnetic sensor (magnetic sensor module) according to the embodiments. FIG. 12 is a cross-sectional view of an element connecting body in a comparative example, and FIG. 13 is a plan view of a fixed magnetic layer and a permanent magnet layer in the comparative example, and schematically illustrates a magnetic domain structure. FIG. 14 is a cross-sectional view of an element portion and a permanent magnet layer of the related art.

A magnetic sensor module having a magnetic sensor 1 including magnetoresistance effect elements according to an embodiment may be used as, for example, a geomagnetic sensor mounted in a mobile device such as a mobile phone.

As illustrated in FIG. 10, the magnetic sensor 1 includes a sensor unit 6 formed by bridge-connecting magnetoresistance effect elements 2 and 3 and fixed resistors 4 and 5, and an integrated circuit (IC) 11 electrically connected to the sensor unit 6. The IC 11 includes an input terminal 7, a ground terminal 8, a differential amplifier 9, and an external output terminal 10.

As illustrated in FIG. 1A, element portions 12 and intermediate permanent magnet layers (first permanent magnet layers) 60 are alternately formed in the X direction in the figure, and outer permanent magnet layers (second permanent magnet layers) 65 are provided on both sides of the element portions 12 located at both sides in the X direction in the figure. An element connecting body 61 extending in a band shape is formed of the element portions 12, the intermediate permanent magnet layers 60, and the outer permanent magnet layers 65. As illustrated in FIG. 1A, an element length L1 (excluding the outer permanent magnet layers 65) of the element connecting body 61 is longer than an element width W1.

A plurality of element connecting bodies 61 are disposed side by side with intervals therebetween in the element width direction (Y direction). The outer permanent magnet layers 65 provided at both ends of the respective element connecting bodies 61 are connected using an electrode layer 62 so that the magnetoresistance effect elements 2 and 3 are formed into a meandering shape.

One end of each of the element connecting bodies 61 located at both ends of each of the meandering elements 2 and 3 is connected to an electrode layer 62 connected to the input terminal 7, the ground terminal 8, and output extracting portions 14 (see FIG. 10). The electrode layers 62 have a low resistance than the permanent magnet layers 60 and 65, and are made of a non-magnetic conductive material such as Al, Ta, or Au.

All the element portions 12 of the magnetoresistance effect elements 2 and 3 have the same stacking structure illustrated in FIG. 9. FIG. 9 illustrates a cross section taken in the thickness direction as viewed from the direction parallel to the element width W1.

The element portions 12 may be configured such that, for example, an antiferromagnetic layer 33, a fixed magnetic layer 34, a non-magnetic layer 35, and a free magnetic layer 36 are stacked and deposited in order from the bottom, and the surface of the free magnetic layer 36 is coated with a protective layer 37. The element portions 12 may be formed using, for example, sputtering.

The antiferromagnetic layer 33 is made of an antiferromagnetic material such as Ir—Mn alloy (iridium-manganese alloy). The fixed magnetic layer 34 is made of a soft magnetic material such as Co—Fe alloy (cobalt-iron alloy). The non-magnetic layer 35 may be made of Cu (copper) or the like. The free magnetic layer 36 is made of a soft magnetic material such as Ni—Fe alloy (nickel-iron alloy). The protective layer 37 may be made of Ta (tantalum) or the like. In the above configuration, the non-magnetic layer 35 may be a giant magnetoresistance effect element (GMR element) made of a non-magnetic conductive material such as Cu, or may also be a tunnel magnetoresistance effect element (TMR element) made of an insulating material such as Al₂O₃. Furthermore, the stacking configuration of the element portions 12 illustrated in FIG. 9 is merely an example, and any other stacking configuration may be used.

In the element portions 12, the magnetization direction of the fixed magnetic layer 34 is fixed due to the antiferromagnetic coupling between the antiferromagnetic layer 33 and the fixed magnetic layer 34. As illustrated in FIGS. 1A, 1B, and 9, the fixed magnetization direction (P direction) of the fixed magnetic layer 34 is oriented in the element width direction (Y direction). That is, the fixed magnetization direction (P direction) of the fixed magnetic layer 34 is perpendicular to the longitudinal direction of the element connecting bodies 61.

On the other hand, the magnetization direction (F direction) of the free magnetic layer 36 varies in accordance with an external magnetic field. In this embodiment, a bias magnetic field toward the X direction in the figures acts on the element portions 12 from the permanent magnet layers 60 and 65. Therefore, the magnetization of the free magnetic layer 36 of the element portions 12 is oriented in the X direction in the figures in the non-magnetic field state.

As illustrated in FIG. 8, an external magnetic field Y1 acts along the same direction as the fixed magnetization direction (P direction) of the fixed magnetic layer 34, and the magnetization direction (F direction) of the free magnetic layer 36 is oriented in the direction of the external magnetic field Y1. Then, the fixed magnetization direction (P direction) of the fixed magnetic layer 34 and the magnetization direction (F direction) of the free magnetic layer 36 are made approximately parallel, and the value of electrical resistance decreases.

On the other hand, as illustrated in FIG. 8, an external magnetic field Y2 acts along the direction opposite to the fixed magnetization direction (P direction) of the fixed magnetic layer 34, and the magnetization direction (F direction) of the free magnetic layer 36 is oriented in the direction of the external magnetic field Y2. Then, the fixed magnetization direction (P direction) of the fixed magnetic layer 34 and the magnetization direction (F direction) of the free magnetic layer 36 are made approximately antiparallel, and the value of electrical resistance increases.

As illustrated in FIG. 1B, the magnetoresistance effect elements 2 and 3 are formed on a substrate 16. The magnetoresistance effect elements 2 and 3 are coated with an insulating layer 17 such as an Al₂O₃ or SiO₂ layer. Also, the space between the element connecting bodies 61 of the magnetoresistance effect elements 2 and 3 is also filled with the insulating layer 17. The insulating layer 17 is formed using, for example, sputtering.

As in FIG. 1B, the top surface of the insulating layer 17 is flattened using, for example, a chemical-mechanical polishing (CMP) technique. However, the top surface of the insulating layer 17 may be provided with irregularities in accordance with the steps between the element connecting bodies 61 and the substrate 16.

In the embodiment illustrated in FIGS. 1A and 1B, soft magnetic bodies 18 that exert a magnetic shielding effect are provided between the element connecting bodies 61 of the magnetoresistance effect elements 2 and 3 and are also provided outside the outermost element connecting bodies 61. The soft magnetic bodies 18 are formed into a thin film using, for example, sputtering or plating. The soft magnetic bodies 18 may be made of NiFe, CoFe, CoFeSiB, CoZrNb, or the like. The soft magnetic bodies 18 have a length L2 that is longer than the element length L1 of the element connecting bodies 61. As illustrated in FIG. 1A, each of the soft magnetic bodies 18 has extending portions 18a configured to extend in the longitudinal direction from both sides in the longitudinal direction (X direction) of the element connecting bodies 61.

As illustrated in FIG. 1B, the soft magnetic bodies 18 are formed on the insulating layer 17 between the element portions 12. An insulating protective layer is placed on the top of the soft magnetic bodies 18 and also between the soft magnetic bodies 18 although it is not illustrated in the figure.

The dimensions will be described.

The element width W1 of the element portions 12 of the magnetoresistance effect elements 2 and 3 ranges from about 2 to 10 μm (see FIG. 1A). The element portions 12 have an element length L5 in the range from about 1 to 10 μm (see FIG. 1A). The element portions 12 have a thickness T2 in the range from about 200 to 400 Å (see FIG. 1B). The element portions 12 have an aspect ratio (element length L5/element width W1) of about 0.1 to 4.

Each of the intermediate permanent magnet layers 60 has a length L3 in the range from about 0.5 to 5 μm (see FIG. 1A). Further, each of the intermediate permanent magnet layers 60 has a width W3 in the range from about 3 to 12 μm (see FIG. 1A). Preferably, W3 is larger than W1. The thickness of the intermediate permanent magnet layers 60 is in the range from about 150 to 1000 Å.

Each of the outer permanent magnet layers 65 has a length L4 in the range from about 5 to 10 μm (see FIG. 1A). The thickness of the outer permanent magnet layers 65 is preferably equal to the thickness of the intermediate permanent magnet layers 60.

An interval T5 between the element connecting bodies 61 in the element width direction ranges from about 2 to 10 μm (see FIG. 1A).

Further, the length L1 of the element connecting bodies 61 is in the range from about 50 to 200 μm.

Further, in this embodiment, the soft magnetic bodies 18 have a width W2 in the range from about 1 to 6 μm (see FIG. 1A) when the magnetic sensor 1 is used as a geomagnetic sensor. Further, the length L2 of the soft magnetic bodies 18 is in the range from about 80 to 200 μm (see FIG. 1A). Further, the soft magnetic bodies 18 have a thickness T3 in the range from about 0.2 to 1 μm (see FIG. 1B). The extending portions 18a of the soft magnetic bodies 18 have a length T8 greater than or equal to about 10 μm (see FIG. 1A).

In the embodiment illustrated in FIGS. 1A and 1B, the distance (distance in the Y direction) T1 between the soft magnetic bodies 18 is greater than or equal to the width W2 of soft magnetic bodies 18 and ranges from about 2 to 8 μm (see FIG. 1B). The distance T4 between each of the element portions 12 and one of the soft magnetic bodies 18 adjacent to the element portion 12 in the Y direction meets 0<T4<3 μm (see FIG. 1B). Further, the distance T5 between the soft magnetic bodies 18 and the element portions 12 in the height direction (Z direction) ranges from about 0.1 to 1 μm (see FIG. 1B).

The magnetic sensor 1 illustrated in FIGS. 1A and 1B is configured to detect the geomagnetism along the direction parallel to the Y direction (element width direction) in the figures. Therefore, the Y direction in the figures serves as a sensitivity axis direction, and the X direction (element length direction) perpendicular to the Y direction in the figures is the longitudinal direction of the element connecting bodies 61. The fixed magnetization direction (P direction) of the fixed magnetic layer 34 is oriented in the sensitivity axis direction, that is, the Y direction in the figures.

FIG. 2 illustrates an example modification of the embodiment illustrated in FIGS. 1A and 1B. In the embodiment illustrated in FIG. 2, the magnetoresistance effect elements 2 and 3 are configured such that electrode layers 62 that connect the ends of the element connecting bodies 61 to one another is formed into a linear shape (band shape) extending in the Y direction, and the electrode layers 62 extend underneath the soft magnetic bodies 18 with an insulating layer therebetween. That is, the electrode layers 62 and the soft magnetic bodies 18 intersect each other in the height direction (in FIG. 2, the Z direction). The electrode layers 62 may be formed above the magnetic bodies 18 rather than below if portions of the electrode layers 62 that are connected to the element connecting bodies 61 are electrically isolated from the soft magnetic bodies 18.

In FIGS. 1A and 1B, the electrode layers 62 are formed so as to extend around the soft magnetic bodies 18 in plan view. In FIG. 2, however, the electrode layers 62 and the soft magnetic bodies 18 intersect each other in the height direction (in FIG. 2, the Z direction), leading to a reduction in the length in the X direction of the magnetoresistance effect elements 2 and 3 in the figures and a reduction in the wiring resistance of the electrode layers 62. In addition, because of the low insulation between the electrode layers 62 and the soft magnetic bodies 18 (where the insulating layer 17 illustrated in FIG. 1B is provided therebetween), even a short circuit may have substantially no influence on sensor characteristics. Furthermore, the electrode layers 62 are formed of non-magnetic good conductors, resulting in a lower parasitic resistance than that when the electrode layers 62 are formed of permanent magnet layers. If the electrode layers 62 are formed of permanent magnet layers, a bias magnetic field may have an influence on the soft magnetic bodies 18 and may cause a reduction in the shielding effect. This problem does not occur in this embodiment.

In this embodiment, as illustrated in the cross-sectional view in FIG. 3, the antiferromagnetic layer 33, the fixed magnetic layer 34, and the non-magnetic layer 35 of each of the element portions 12 are not separated at the positions at which the permanent magnet layers 60 and 65 are to be formed, and extend over the entirety in the element length direction (in FIG. 3, the X direction) of the element connecting bodies 61. At the positions where the permanent magnet layers 60 and 65 are to be formed, the protective layer 37 and the free magnetic layer 36 of the element portions 12 are removed by ion milling or the like to form recessed portions 63. Therefore, the non-magnetic layer 35 is exposed from the bottom surfaces 63a of the recessed portions 63. The permanent magnet layers 60 and 65 are provided in the recessed portions 63. The interfaces of the antiferromagnetic layer 33, the fixed magnetic layer 34, the non-magnetic layer 35, the free magnetic layer 36, and the protective layer 37 are parallel to the X-Y plane (FIGS. 3 and 6).

As illustrated in an enlarged cross-sectional view of FIG. 6, preferably, the bottom surfaces 63a of the recessed portions 63 are located midway in the thickness direction (in FIG. 6, the Z direction) of the non-magnetic layer 35. The bottom surfaces 63a may be located at positions on the upper surface 35a or lower surface 36b of the non-magnetic layer 35. However, positioning the bottom surfaces 63a midway in the thickness direction of the non-magnetic layer 35 may avoid a portion of the free magnetic layer 36 from remaining below the recessed portions 63 (permanent magnet layers 60 and 65). That is, the free magnetic layer 36 is completely removed at the positions where the recessed portions 63 are formed. Additionally, there is no inconvenience that a portion of the fixed magnetic layer 34 is removed when the recessed portions 63 are formed using ion milling or the like. Moreover, with the intervention of the non-magnetic layer 35 between the fixed magnetic layer 34 and the permanent magnet layers 60 and 65, the magnetic coupling between the fixed magnetic layer 34 and the permanent magnet layers 60 and 65 can be prevented.

In this embodiment, as illustrated in FIGS. 3 and 6, the overall thickness of the free magnetic layer 36 faces the permanent magnet layers 60 and 65 in the element length direction (X direction). Therefore, a bias magnetic field can be supplied as desired to the overall free magnetic layer 36 from the permanent magnet layers 60 and 65 in the element length direction (in FIGS. 3 and 6, the X direction), and the uniaxial anisotropy of the free magnetic layer 36 can be improved.

In this embodiment, furthermore, as illustrated in FIGS. 3, 5, and 6, the fixed magnetic layer 34 is formed as a single layer formed over the entirety in the element length direction (in FIGS. 3, 5, and 6, the X direction) of the element connecting bodies 61 without being separated at the positions where the permanent magnet layers 60 and 65 are to be formed.

Here, if the fixed magnetic layer 34 is separated at the positions where the recessed portions 63 are formed, as described hereinafter, it is difficult to improve the uniaxial anisotropy of the fixed magnetic layer 34.

A comparative example (FIG. 12) in which the fixed magnetic layer 34 is formed so as to be separated will be described. In FIG. 12, element portions 12 are separated and completely removed at positions where permanent magnet layers 60 and 65 are to be formed. The permanent magnet layers 60 and 65 are provided between the separated element portions 12. In the example illustrated in FIG. 12, the fixed magnetic layer 34 is separated at positions where the permanent magnet layers 60 are to be formed, and the permanent magnet layers 60 and 65 are arranged so as to face the side surfaces of the separated portions of the fixed magnetic layer 34. The individual separation of the fixed magnetic layer 34 that is formed as a single layer weakens the magnetic domain structures of the individual portions of the fixed magnetic layer 34 (which become unstable). In addition, a bias magnetic field is supplied to the overall fixed magnetic layer 34 in a manner similar to that of the free magnetic layer 36 in the element length direction (in FIG. 12, the X direction) from the permanent magnet layers 60 and 65, as illustrated in FIG. 13 (which is a plan view of the separated portions of the fixed magnetic layer 34), the axis of the magnetization in vicinity of the side portions of the fixed magnetic layer 34 is easily inclined from the sensitivity axis direction (Y direction), resulting in a reduction in the uniaxial anisotropy of fixed magnetic layer 34.

In this embodiment, in contrast, the fixed magnetic layer 34 remains as it is below the permanent magnet layers 60 and 65, and, as in FIGS. 3, 5, and 6, the fixed magnetic layer 34 is formed as a single layer without being separated. Thus, unlike the comparative example illustrated in FIGS. 12 and 13, the magnetic domain structure of the fixed magnetic layer 34 is not separated. Furthermore, since the fixed magnetic layer 34 is formed so as to extend over the entirety in the element length direction (X direction) of the element connecting bodies 61 without being separated, the exchange coupling magnetic field (Hex) or plateau magnetic field (Hpl) along the sensitivity axis direction, which is produced between the fixed magnetic layer 34 and the antiferromagnetic layer 33, can be more effectively increased. Moreover, since the fixed magnetic layer 34 and the permanent magnet layers 60 and 65 do not face each other in the element length direction (X direction), unlike the comparative example, a strong bias magnetic field is not directly supplied from the permanent magnet layers 60 and 65 to the fixed magnetic layer 34.

In this embodiment, a leakage magnetic field produced around and below the permanent magnet layers 60 and 65 slightly acts on the fixed magnetic layer 34 located below the permanent magnet layers 60 and 65. However, the formation of the fixed magnetic layer 34 as a single layer without separation in the manner as in this embodiment can promote the single magnetic domain structure of the overall fixed magnetic layer 34, and can provide effective improvement of the uniaxial anisotropy.

According to this embodiment, therefore, the uniaxial anisotropy of the fixed magnetic layer 34 and the free magnetic layer 36 can be improved, and the detection accuracy can be improved.

Furthermore, in the comparative example in FIGS. 12 and 13 where the fixed magnetic layer 34 and the antiferromagnetic layer 33 are separated and the permanent magnet layers 60 and 65 are provided between the element portions 12, the electrical contact between the permanent magnet layers 60 and 65 and the element portions 12 is established on each side surface and therefore the parasitic resistance is likely to increase. In contrast, as in this embodiment, the electrical contact between the permanent magnet layers 60 and 65 and the element portions 12 is planar contact, thus allowing a reduction in parasitic resistance.

Further, as illustrated in FIG. 3, low-resistance layers 64 having a lower resistance value than the intermediate permanent magnet layers 60 are formed on the top surface of the intermediate permanent magnet layers 60 (the surface opposite to the surface oriented toward the fixed magnetic layer 34) in such a manner that the low-resistance layers 64 overlap the intermediate permanent magnet layers 60. Preferably, the low-resistance layers 64 are formed of non-magnetic good conductors made of Au, Al, Cu, or the like. Similarly to the intermediate permanent magnet layers 60, the low-resistance layers 64 may be formed using sputtering, plating, or the like. As illustrated in FIG. 3, the formation of the low-resistance layers 64 so as to overlap the intermediate permanent magnet layers 60 can more effectively reduce the parasitic resistance. As describe above, the electrode layers 62 serving as low-resistance layers are formed so as to overlap the outer permanent magnet layers 65. With this configuration, the parasitic resistance components that do not contribute to the change in magnetic resistance can be effectively reduced.

In FIGS. 2 and 3, the element portions 12 and the intermediate permanent magnet layers 60 are connected in series in the direction perpendicular to the element width, and the outer permanent magnet layers 65 are formed outside the element portions 12 and the intermediate permanent magnet layers 60. In this case, the bias magnetic fields in the permanent magnet layers 60 are accumulated in the center of the element, and therefore the outside bias magnetic field becomes weaker than that near the center. Thus, preferably, the length of each of the outer permanent magnet layers 65 in the direction perpendicular to the element width is longer than the length of each of the intermediate permanent magnet layers 60. Furthermore, with the separation of the formation process, similar advantages can also be achieved by making the thickness of the outer permanent magnet layers 65 larger than the thickness of the intermediate permanent magnet layers 60.

Moreover, the magnetic field is significantly strong in the vicinity of the corners of the intermediate permanent magnet layers 60 and the outer permanent magnet layers 65. Thus, making the width W3 of the permanent magnet layers 60 and 65 larger than the element width W1 can prevent the portion of the magnetic field having the largest intensity from having a direct influence on the element portions 12, and can also increase the margin of the alignment accuracy in pattern formation.

In addition, the increase in the aspect ratio (element length L5/element width W1) of the element portions 12 held between the permanent magnet layers 60 and 65 (see FIG. 4) may prevent the bias magnetic field from the permanent magnet layers 60 and 65 from being supplied to the entirety in the element length direction of the free magnetic layer 36 of the element portions 12, and may prevent effective improvement of the uniaxial anisotropy. Therefore, preferably, the aspect ratio of the element portions 12 is low in order to appropriately supply the bias magnetic field to the entirety in the element length direction of the free magnetic layer 36. Specifically, the aspect ratio of the element portions 12 is preferably less that or equal to 3, and more preferably less than 1.

The recessed portions 63 illustrated in FIG. 3 can be formed by, for example, forming a lift-off resist pattern on the element portions 12 and removing the protective layer 37 and the free magnetic layer 36 (and also the non-magnetic layer 35) of parts of the element portions 12 that are not covered with the lift-off resist pattern by etching. Permanent magnet layers 60 and 65 are deposited by sputtering or the like while the lift-off resist pattern is left as it is, and low-resistance layers 64 are further deposited on the permanent magnet layers 60 and 65 by sputtering or the like. Formation can be completed by removing the lift-off resist pattern.

The overall element portions 12 at the positions where the outer permanent magnet layers 65 are to be formed may be removed (that is, the portions of the fixed magnetic layer 34 and the antiferromagnetic layer 33 may also be removed) so as to achieve a positional relationship between the element portions 12 and the outer permanent magnet layers 65 so that the side surfaces of the element portions 12 and the side surfaces of the outer permanent magnet layers 65 face each other. At the positions of the outer permanent magnet layers 65, because of the outermost peripheral position of the element portions 12, even when the fixed magnetic layer 34 is removed, in the overall element portions 12, the fixed magnetic layer 34 is not separated but is formed into an integral shape. Further, similarly to the intermediate permanent magnet layers 60, the outer permanent magnet layers 65 may also be formed in recessed portions formed in the element portions 12. In this configuration, the magnetization of the free magnetic layer 36 can be prevented from fluctuating at both side positions, and the direction of the magnetization of the overall free magnetic layer 36 can be fixed to one direction as desired, leading to improvement in characteristics. Additionally, the outer permanent magnet layers 65 and the intermediate permanent magnet layers 60 can be formed using the same steps.

In the embodiments illustrated in FIGS. 1A, 1B, and 2, the soft magnetic bodies 18 are provided. Preferably, the soft magnetic bodies 18 include the extending portions 18a extending in the element length direction from both sides in the element length direction (X direction) of the element connecting bodies 61. Thus, a transverse magnetic field (magnetic field along the X direction) is likely to more effectively pass through the soft magnetic bodies 18. In the embodiments, with the provision of the soft magnetic bodies 18, the magnetic shielding effect for the transverse magnetic field can be improved, and the detection accuracy for a magnetic field along the sensitivity axis direction (Y direction) can also be improved.

In the embodiments, the provision of the soft magnetic bodies 18 is optional.

Each of the magnetoresistance effect elements 2 and 3 may include one or a plurality of element portions 12. A plurality of element portions 12 are provided so that the magnetoresistance effect elements 2 and 3 are formed into a meandering shape, thus advantageously allowing an increase in element resistance and a reduction in power consumption.

Further, the number of magnetoresistance effect elements 2 and 3 and the number of fixed resistors 4 and 5 may be one. However, a bridge circuit may be formed in the manner as illustrated in FIG. 10, and outputs obtained from the output extracting portions 14 are fed to the differential amplifier 9 to produce a differential output. Therefore, a large output value can be obtained and high-accuracy magnetic field detection can be performed.

Further, in FIGS. 1A, 1B, and 2, the soft magnetic bodies 18 are provided on both sides of the element connecting bodies 61. Alternatively, the soft magnetic bodies 18 may also be provided above or below the element connecting bodies 61 with an insulating layer therebetween.

The fixed magnetization direction (P direction) of the fixed magnetic layer 34 may be changed in the same chip, or two chips having the same fixed magnetization direction (P direction) may be used to form a full-bridge configuration.

In FIGS. 3 and 6, the element portions 12 are configured such that the antiferromagnetic layer 33, the fixed magnetic layer 34, the non-magnetic layer 35, the free magnetic layer 36, and the protective layer 37 are stacked in this order from the bottom. That is, in this configuration, the free magnetic layer 36 is provided above the fixed magnetic layer 34.

In contrast, in an embodiment illustrated in FIG. 7, the element portions 12 are configured such that an underlying layer 40 (which may not necessarily be formed), the free magnetic layer 36, the non-magnetic layer 35, the fixed magnetic layer 34, the antiferromagnetic layer 33, and the protective layer 37 are stacked in this order from the bottom. That is, in FIG. 7, the free magnetic layer 36 is formed below the fixed magnetic layer 34. In this configuration, it is necessary to first form the permanent magnet layers 60 and 65. After that, the element portions 12 are formed. At this time, the surface on which the element portions 12 are formed serves as the interface with irregularities between a substrate and the permanent magnet layers 60 and 65. For this reason, the configuration illustrated in FIGS. 3 and 6 in which the free magnetic layer 36 is provided above the fixed magnetic layer 34 allows more appropriate and easier formation of the element portions 12 because the element portions 12 are first formed on the planar surface of the substrate prior to the formation of the permanent magnet layers 60 and 65.

In order to implement the embodiment illustrated in FIG. 7, the permanent magnet layers 60 and 65 are formed on a substrate (if the low-resistance layers 64 are provided, the low-resistance layers 64 are formed prior to the formation of the permanent magnet layers 60 and 65). After that, the underlying layer 40 and the free magnetic layer 36 are deposited between the permanent magnet layers 60 and 65 in this order from the bottom. Here, the top surface of the permanent magnet layers 60 and 65 and the top surface of the free magnetic layer 36 are flattened using CMP or the like. Thereafter, on the flat surface, a thin magnetic layer, the non-magnetic layer 35, the fixed magnetic layer 34, the antiferromagnetic layer 33, and the protective layer 37 are stacked in this order from the bottom. The formation of a thin magnetic layer is performed because of the following reason: Basically, it is preferable that the free magnetic layer 36, the non-magnetic layer 35, and the fixed magnetic layer 34 be continuously formed by film deposition. In the embodiment illustrated in FIG. 7, however, after the formation of the free magnetic layer 36, the deposition of the subsequent layers is interrupted. For example, a magnetic layer, which may be as thin as several angstroms, does not substantially function as a free magnetic layer in a portion where the magnetic layer overlaps the permanent magnet layers 60 and 65, but may function integrally with the free magnetic layer 36 in a portion where the magnetic layer overlaps the free magnetic layer 36. Alternatively, after the layers up to the non-magnetic layer 35 are deposited between the permanent magnet layers 60 and 65, the top surface of the permanent magnet layers 60 and 65 and the top surface of the non-magnetic layer 35 may be flattened using CMP or the like. After that, on the flat surface, a thin non-magnetic layer, the fixed magnetic layer 34, the antiferromagnetic layer 33, and the protective layer 37 may be stacked in this order from the bottom. The manufacturing method described above is merely an example and it is to be understood that the formation may also be performed using any other manufacturing method.

The magnetic sensor 1 according to this embodiment may be used as, for example, a geomagnetic sensor (magnetic sensor module) illustrated in FIG. 11. Each of an X-axis magnetic field sensing unit 50, a Y-axis magnetic field sensing unit 51, and a Z-axis magnetic field sensing unit 52 includes a sensor unit with the bridge circuit illustrated in FIG. 10. In the X-axis magnetic field sensing unit 50, the fixed magnetization directions (P directions) of the fixed magnetic layers 34 of the element portions 12 of the magnetoresistance effect elements 2 and 3 are oriented in the X direction that is the sensitivity axis. In the Y-axis magnetic field sensing unit 51, the fixed magnetization directions (P directions) of the fixed magnetic layers 34 of the element portions 12 of the magnetoresistance effect elements 2 and 3 are oriented in the Y direction that is the sensitivity axis. In the Z-axis magnetic field sensing unit 52, the fixed magnetization directions (P directions) of the fixed magnetic layers 34 of the element portions 12 of the magnetoresistance effect elements 2 and 3 are oriented in the Z direction that is the sensitivity axis.

The X-axis magnetic field sensing unit 50, the Y-axis magnetic field sensing unit 51, the Z-axis magnetic field sensing unit 52, and an application specific integrated circuit (ASIC) 11 are disposed on a base 53. The plane in which the magnetoresistance effect elements 2 and 3 of the X-axis magnetic field sensing unit 50 and the Y-axis magnetic field sensing unit 51 are formed is the X-Y plane while the plane in which the magnetoresistance effect elements 2 and 3 of the Z-axis magnetic field sensing unit 52 are formed is the X-Z plane. The plane in which the magnetoresistance effect elements 2 and 3 of the Z-axis magnetic field sensing unit 52 are formed is perpendicular to the plane in which the magnetoresistance effect elements 2 and 3 of the X-axis magnetic field sensing unit 50 and the Y-axis magnetic field sensing unit 51 are formed.

In this embodiment, at least two of the X-axis magnetic field sensing unit 50, the Y-axis magnetic field sensing unit 51, and the Z-axis magnetic field sensing unit 52 may be disposed on the base 53. In this case, in each sensing unit, the magnetic shielding of the magnetic field from the direction perpendicular to the sensitivity axis direction can be achieved as desired, and the geomagnetism along the sensitivity axis directions of the respective sensing units can be detected as desired.

In addition to the configuration illustrated in FIG. 11, a module having a combination of the geomagnetic sensor illustrated in FIG. 11, an acceleration, and other suitable sensors may be provided.

1. A magnetic sensor comprising a magnetoresistance effect element,
the magnetoresistance effect element including:
an element portion including:
a fixed magnetic layer having a fixed magnetization direction,
a non-magnetic layer stacked on the fixed magnetic layer, and
a free magnetic layer stacked on the non-magnetic layer, the non-magnetic layer being provided between the fixed magnetic layer and the free magnetic layer, the free magnetic layer having a magnetization direction varying in response to an external magnetic field,
the fixed magnetization direction of the fixed magnetic layer being oriented in an element width direction of the element portion that is a sensitivity axis direction,
the element portion having recessed portions at a plurality of positions midway in an element length direction thereof perpendicular to the element width direction, the recessed portions being formed in a thickness direction of the element portion,
a first permanent magnet layer provided in the recessed portions, and
an element connecting body including the element portion and the first permanent magnet layer,
wherein the recessed portions are formed in an upper surface or a lower surface of the non-magnetic layer or formed midway in a thickness direction of the non-magnetic layer from the free magnetic layer,
wherein the first permanent magnet layer formed in the recessed portions and an overall thickness of the free magnetic layer face each other in the element length direction, and
wherein the fixed magnetic layer extends, without being separated, over an entirety in an element length direction of the element connecting body.

2. The magnetic sensor according to claim 1, wherein the element portion is configured such that the fixed magnetic layer, the non-magnetic layer, and the free magnetic layer are stacked in order from the bottom.

3. The magnetic sensor according to claim 1, wherein the recessed portions are formed midway in the thickness direction of the non-magnetic layer from the free magnetic layer.

4. The magnetic sensor according to claim 1, wherein a non-magnetic low-resistance layer having a lower resistance value than the first permanent magnet layer is formed on a surface of the first permanent magnet layer opposite to a surface facing the fixed magnetic layer in such a manner that the non-magnetic low-resistance layer overlaps the first permanent magnet layer.

5. The magnetic sensor according to claim 1, wherein the magnetoresistance effect element further includes second permanent magnet layers provided on both sides in the element length direction of the element portion in such a manner that the second permanent magnet layers are in contact with the element portion or are spaced apart from the element portion.

6. The magnetic sensor according to claim 5, wherein the element portion further has recessed portions at both sides in the element length direction thereof, and the second permanent magnet layers are formed in the recessed portions.

7. The magnetic sensor according to claim 5, wherein a length in an element length direction of each of the second permanent magnet layers is longer than a length in an element length direction of the first permanent magnet layer.

8. The magnetic sensor according to claim 5, wherein a width of the first permanent magnet layer and a width of each of the second permanent magnet layers are larger than a width of the element portion.

9. The magnetic sensor according to claim 1, wherein the element connecting body includes a plurality of element connecting bodies, the plurality of element connecting bodies being arranged with intervals therebetween in the element width direction, and
wherein outer permanent magnet layers provided at both sides of each of the plurality of element connecting bodies are electrically connected to each other using a non-magnetic connection layer so that the plurality of element connecting bodies are formed into a meandering shape.

10. A magnetic sensor module comprising a plurality of magnetic sensors each comprising the magnetic sensor according to claim 1,
wherein magnetoresistance effect elements of the plurality of magnetic sensors are arranged so that a sensitivity axis of a magnetoresistance effect element of at least one of the plurality of magnetic sensors is perpendicular to a sensitivity axis of a magnetoresistance effect element of the other magnetic sensors.
